(19) United States
(12) Patent Application Publication
(10) Pub. No.: US 2012/0126810 A1
(43) Pub. Date: May 24, 2012

(54) MAGNETIC RESONANCE PH MEASUREMENTS USING LIGHT ENDOWED WITH ORBITAL ANGULAR MOMENTUM

(75) Inventors: Daniel Elgort, New York, NY (US); Remus Albu, Forest Hills, NY (US)

(73) Assignee: KONINKLIJKE PHILIPS ELECTRONICS N.V., EINDHOVEN (NL)

(21) Appl. No.: 13/386,674

(22) PCT Filed: Jul. 9, 2010
(86) PCT No.: PCT/IB2010/053147

§ 371 Date: Jan. 24, 2012

Related U.S. Application Data
(60) Provisional application No. 61/232,814, filed on Aug. 11, 2009.

(51) Int. Cl. G01R 33/44

(52) U.S. Cl. 324/307

(57) ABSTRACT

In a pH measurement system, a magnet defines a BO magnetic field with which selected dipoles preferentially align in an examination region. A orbital angular momentum system endows electromagnetic (EM) radiation with orbital angular momentum (OAM) and transmits the OAM endowed EM radiation to the examination region to at least one of (1) enhance the preferential alignment of the selected dipoles with the BO magnetic field and (2) excite the aligned dipoles to resonate. A receive coil receives resonance signals from the resonating dipoles. An analysis or measurement unit determines a pH in the examination region by analyzing the resonance signals.

The present application relates to the magnetic resonance arts. It finds particular application in using magnetic resonance (MR) to measure pH, and will be described with particular reference thereto.

Typically when measuring pH in a patient, a fluid sample is collected from the patient and taken to a laboratory which measures the pH of the fluid using bench-top laboratory equipment. This approach, however, is limited to samples from a single time point and the measurement may not accurately reflect the pH levels inside an organ of interest.

An electrode directly inserted into the organ of interest can make continuous pH measurements over an extended period of time directly from inside the organ of interest. However, this approach requires an invasive procedure to implant the electrode. pH can also be measured using a magnetic resonance imaging (MRI) or a magnetic resonance spectroscopy (MRS) system. MRI scanners and MRS spectrometers are able to measure pH by measuring the changes in T2 relaxation rate or chemical shift frequency. The changes in the T2 relaxation rate or the chemical shift frequency are proportionally correlated to changes in pH. Unfortunately, this approach requires routine testing and screening using an MRI or MRS scanner which is cumbersome and expensive.

The present application provides a new and improved pH measurement device which overcomes the above-referenced problems and others.

In accordance with one aspect, a pH measurement system is provided. A magnet defines a B₀ magnetic field with which selected dipoles preferentially align in an examination region. A orbital angular momentum system endows electromagnetic (EM) radiation with orbital angular momentum (OAM) and transmits the OAM endowed EM radiation to the examination region to at least one of (1) enhance the preferential alignment of the selected dipoles with the B₀ magnetic field and (2) excite the aligned dipoles to resonate. A receive coil receives resonance signals from the resonating dipoles. An analysis or measurement unit determines a pH in the examination region by analyzing the resonance signals.

In accordance with another aspect, a method of measuring pH is provided. A B₀ magnetic field is defined with which selected dipoles preferentially align in an examination region. Electromagnetic (EM) radiation X is endowed with orbital angular momentum (OAM). The OAM endowed EM radiation is transmitted to the examination region to at least one of (1) enhance the preferential alignment of the selected dipoles with the B₀ magnetic field and (2) excite the aligned dipoles to resonate. The resonance signals are received from the resonating dipoles and a pH in the examination region is determined by analyzing the resonance signals.

One advantage resides in the real-time measurement of pH.

Another advantage resides in the reduced size of a MR scanner to measure pH.

Another advantage resides in the reduced cost of MR based pH measurement.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

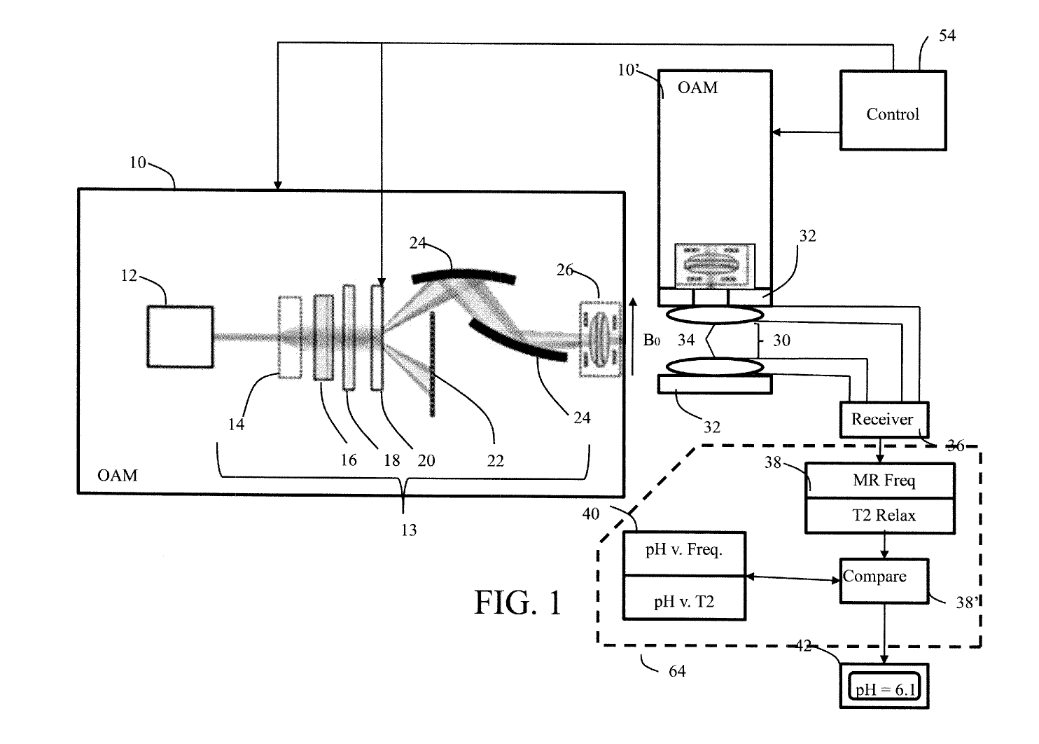

FIG. 1 is a diagram of a pH measurement device, in accordance with the present application.

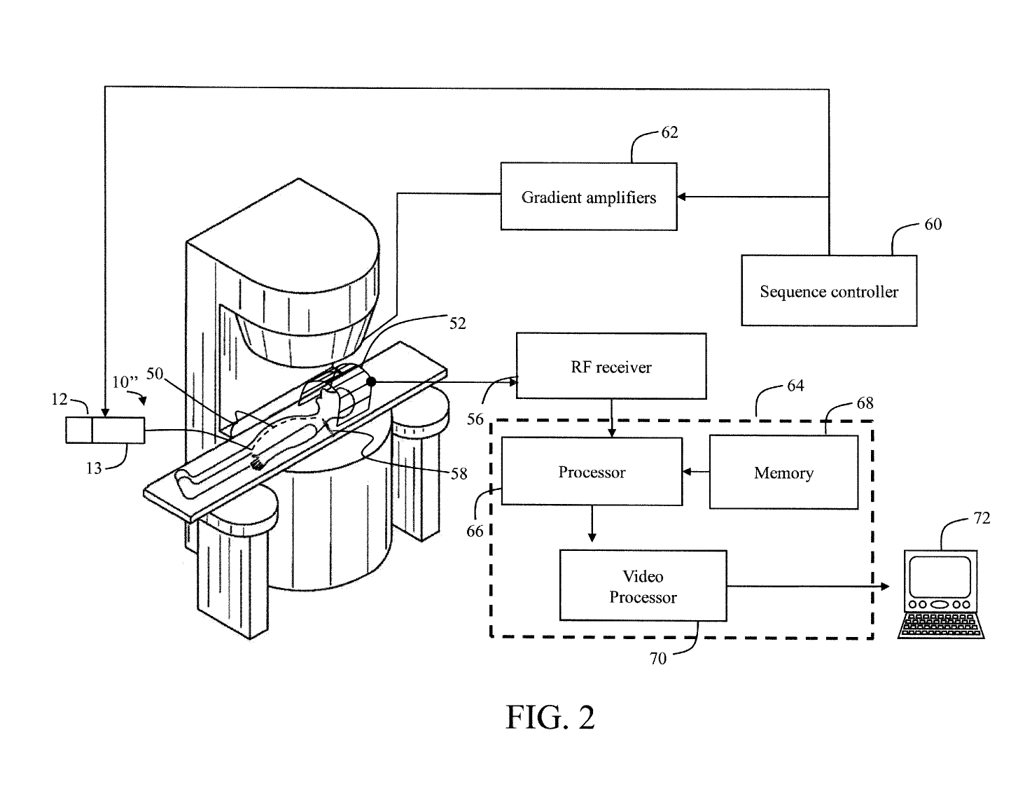

FIG. 2 is a diagrammatic illustration of a magnetic resonance pH measurement apparatus in accordance with the present application.

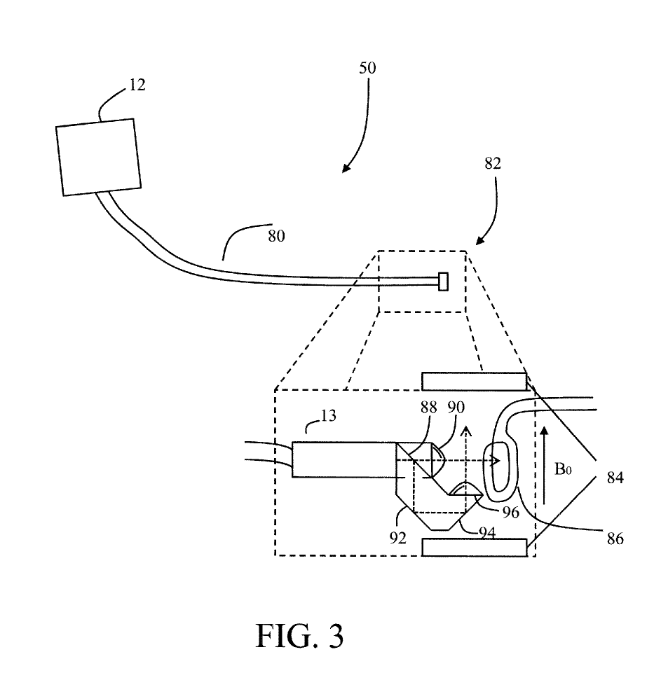

FIG. 3 is a cutaway view of a catheter that carries OAM endowed light capable of being inserted into a patient, in accordance with the present application

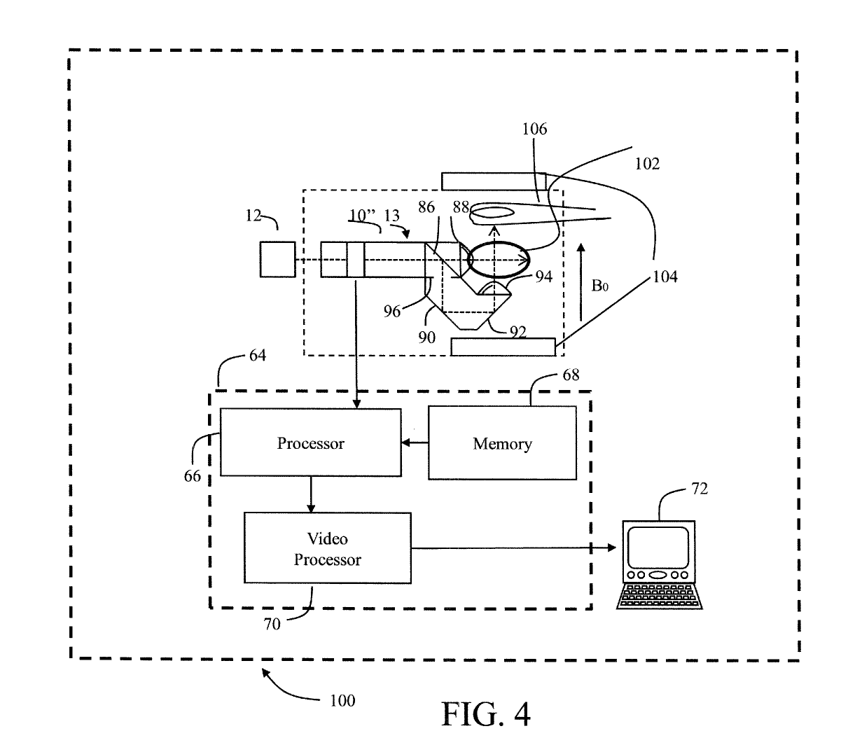

FIG. 4 is a diagrammatic illustration of a tabletop pH measurement apparatus in accordance with the present application.

Orbital angular momentum (OAM) is an intrinsic property of all azimuthal phase-bearing light, independent of the choice of axis about which the OAM is defined. When interacting with an electronically distinct and isolated system, such as a free atom or molecule, OAM can be transferred from the electromagnetic (EM) radiation, such as light, x-rays, or the like to the center of mass of motion.

Various experiments used the interaction of OAM endowed light with matter, for example, optical tweezers, high throughput optical communications channels, optical encryption techniques, optical cooling, entanglements of photons with OAM, and entanglement of molecule quantum numbers with interacting photons' OAM. Because angular momentum is a conserved quantity, the OAM of absorbed photons is transferred in whole to interacting molecules. As a result, the electron states reach saturation spin states, angular momentum of the molecule about its own center of mass is increased and oriented along the propagation axis of the incident light, and magnetrons precession movement of the molecules are oriented along the propagation axis of the incident light. These effects make it possible to hyperpolarize nuclei within fluids by illuminating them with EM carrying spin and OAM.

An analysis of electromagnetic (EM) fields shows that there is a flow of EM energy with a first component that travels along the vector of the beam propagation, and a second component of EM energy that rotates about the axis of the beam propagation. The second component is proportional to the angular change of the potential vector around the beam propagation. This is signification because the rotational energy flow is proportional to the “l”, the OAM value, and the rotational energy transferred to the molecules with which the EM interacts is increase according to the value of the OAM.

When EM carrying spin and OAM is absorbed by molecules, the angular momentum is conserved and the total angular momentum of the system (both the radiation and the matter) is not changed during absorption and emission of the radiation. When a photon is absorbed by an atom, the resulting angular momentum of the atom is equal to the vector sum of its initial angular momentum plus the angular momentum of the absorbed photon.

When a photon interacts with a molecule, only the OAM of the electrons is directly coupled to the optical transitions. The different types of angular momentum are coupled to each other by various interactions such as spin-orbit, spin rotation, hyperfine,

OAM-rotation, and the like. The polarization of the photon flows through the electron orbital to molecule's the nuclear spin, electron spin, and molecular spin via these interactions. The magnitude of the interaction between the photon and the molecule is proportional to the OAM of the photon. Resultantly, the molecular moment aligns in the direction of the propagation axis of the incident light endowed with spin and OAM proportional to that of the OAM content of the incident light.

It is understood that any electromagnetic radiation can be endowed with OAM, not necessarily only visible light. The described embodiment uses visible light, which interacts with the molecules of living tissue without any damaging effects; however, light/radiation above or below the visible spectrum, e.g. infrared, ultraviolet, x-ray, or the like, is also contemplated.

With reference to FIG. 1, an OAM system 10 for endowing light with OAM, includes a white light or other EM radiation source 12 that produces a visible white light or other EM radiation that is send to an OAM endowing module 13 which endows the light or other EM radiation with orbital angular momentum. The OAM endowing module 13 includes a beam expander 14. The beam expander 14 includes an entrance collimator, a dispersing lens, a refocusing lens, and an exit collimator through which the least dispersed frequencies are emitted.

After the beam is expanded, the light beam is circularly polarized. A linear polarizer 16 gives the unpolarized light a single linear polarization. A quarter wave plate 18 circularly polarizes the linearly polarized beam by shifting the phase of the linearly polarized light by 1/4 wavelength. Using circularly polarizing light has the added benefit of polarizing electrons.

The circularly polarized light is passed through an adjustable phase hologram 20 which imparts a selectable amount of OAM and spin to an incident beam. The phase hologram 20 maybe physically embodied in a spatial light modulator as a liquid crystal on silicon (LCoS) panel, or it can be embodied in other optics, such as combinations of cylindrical lens or wave plates, or as a fixed phase hologram.

A spatial filter 22 is placed after the phase hologram to selectively block 0^{th} order diffracted beams, i.e. light with no OAM, and allows light with only one OAM value to pass. Since OAM of the system is conserved, it would be counterproductive to let the entire light pass, because the net OAM transferred to the target molecule would be zero.

The diffracted beams endowed with OAM are collected using concave mirrors 24 and focused on an examination region 30 with an objective lens 26. Alternatively, the mirrors 24 may not be necessary if coherent light is employed. Furthermore, the lens may be replaced or supplemented with an alternate light guide, fiber optics, or the like.

The examination region 30 is defined adjacent to the objective lens 26. Magnets 32 are disposed adjacent to the examination region 30 to generate a B₀ magnetic field traverse to the path of the OAM endowed radiation emitted by the objective lens 26. The OAM system 10 is pulsed to excite resonance in selected polarized dipoles in the examination region 30 which are preferentially aligned with the B₀ field.

In the illustrated embodiment, a second OAM system 10′ directs OAM endowed EM into the examination region 30 to enhance polarization of the selected dipoles. The second OAM system 10′ can be the same as the first OAM system 10 or can include mirrors to re-direct OAM endowed EM radiation from the first OAM system 10 into the examination region 30.

Receive coils 34 receive resonance signals from the polarized dipoles excited to resonance by the OAM endowed EM radiation from the first OAM system 10. A receiver 36 demodulates the signals and a processor 38 in one embodiment determines the magnetic resonance (MR) frequency. The same or another processor 38′ compares the determined resonance frequency with a table, chart, graph, equation, algorithm, or the like from a memory 40 that correlates resonance frequency of the selected dipole with pH. A display 42 displays the pH corresponding to the determined MR frequency for the selected dipole.

In another embodiment, a controller 54 controls the first OAM system 10 to induce spin echoes in the MR signals from the resonating dipoles. The processor 38 determines a rate of decay of the spin echoes, particularly a T2 or T2* relation time, which is compared with relaxation values from a table, chart, graph, equation, algorithm, or the like in the memory 42 which correlate relaxation time values with pH. Alternatively, other types of echoes are contemplated. As another alternative, the relaxation value of the induced resonance signal is measured without inducing echoes.

In another embodiment, the examination region 30 is divided into a plurality of voxels whose pH is each measured. One voxel might correspond to blood and another to a neighboring organ. Spatial encoding is achieved, for example, by gradient magnetic fields produced by weaker, homogeneous magnets, an electromagnetic, or the like. Alternately, the magnets 32 are permanent or electromagnets configured to provide the B₀ field with a permanent gradient in one of more directions to achieve spatial encoding or frequency encoding.

With reference to FIG. 2, in another embodiment, the OAM system is embodied in a catheter or other minimally invasive device 50, such as a needle, endoscope, laparoscope, electronic pill, or the like, and inserted directly into the region of interest. The light or other EM radiation source 12 and the OAM endowing unit 13 may be located outside of the intravenous device connected by a fiber optics channel the light to the tip of the catheter 50. Alternatively, the OAM endowing unit 13 is located adjacent to a distal end of the minimally invasive device. The EM radiation source 12 may be adjacent to the distal end or may be mounted remotely and coupled to the OAM endowing unit 13 by another optic fiber. In this embodiment the main magnets of an MR scanner generate the B₀ field and align the selected dipoles with the B₀ field. The aligned dipoles are caused to resonate by the application of OAM endowed light or other EM radiation from an OAM system 10″. An RF receive coil maybe disposed at the distal, end, or tip of the catheter or arranged externally in or about the examination region e.g. a local receive coil 52. The induced resonance signals are received by the RF receive coil and demodulated by a receiver 56. In another embodiment, blood passing by a trans-dermal, non-invasive, surface probe 58 is illuminated with OAM endowed light as it flows to a through the examination region to induce resonance.

To acquire a pH measurement of the examination region in a subject, the subject is placed inside the imaging region of the MR scanner. A sequence controller 60 communicates with gradient amplifiers 62 and the OAM device 10″ to induce and manipulate resonance in selected dipoles in the region of interest, for example, repeated echo, steady-state, or other resonance sequences, selectively manipulate or spoil resonances, or otherwise generate selected magnetic resonance signals characteristic of the dipoles in the examination region. The generated resonance signals detected by the RF coil assembly 54, 56 are communicated to an analysis or measurement unit 64. The measurement unit 64 determines the pH value by measuring a change in the relaxation value, e.g. a T2 relaxation rate, determined from the detected resonance signals. A measurement processor 66 of the measurement unit 64 acquires echoes from of the region of interest periodically. The processor 66 compares the T2 relaxation value to a look up table, chart, graph, equation, algorithm, or the like stored in a memory 68 that includes T2 relaxation rate values and corresponding pH values and determines the pH value corresponding to the T2 relaxation value of the received MR signal.

In another embodiment, the pH of unknown dipoles is measured by injecting a known reference dipole into the patient. The sequence controller 60 controls the OAM system 10″ to induce resonance concurrently in both the known and unknown dipoles. Typically, the known and unknown dipoles have different characteristic MR frequencies at the strength of the B₀ field. The pH of the reference dipoles is measured as described above and used to correlate relaxation rate of the unknown molecules with pH. The relaxation values of the known reference dipoles is calculated and compared to the look up table stored in memory 68 and a similar table or the like is derived for the unknown dipole by interpolation and extrapolation of a plurality of measured pH values.

In another embodiment, the pH measurement is acquired by measuring changes in the chemical shift values. The processor 66 of the measurement unit 64 calculates the difference between the frequency of the detected resonance signal and the frequency of a reference resonance signal frequency, e.g. the resonance frequency of the measured dipole in the given B₀ field at a pH of 7.0. The chemical shift value is determined from a ratio of the frequency difference over the frequency of the reference signal. When measuring the pH of known molecules, the determined chemical shift value is compared to a look up table, chart, graph, equation, algorithm, or the like stored in memory 68 that includes chemical shift values and corresponding pH values.

In another embodiment, the pH of unknown dipoles is measured by injecting a known reference dipole into the patient. The chemical shift of the unknown and reference dipoles are calculated and the chemical shift of the reference dipole is compared to the look up table stored in memory 68. The determined pH for the reference dipole is then attributed to the measured chemical shift of the unknown dipole.

The resultant pH measurement is processed by a video processor 70 and displayed on a user interface 72 equipped with a human readable display. The interface 72 is, for example, a personal computer or workstation. Rather than producing a video image, the pH measurement can be processed by a printer driver and printed, transmitted over a computer network or the Internet, converted to a digital or analog readout, or the like.

In another embodiment, the surface probe device 58 that carries the OAM device is pressed against the carotid artery(s) where it is sufficiently close that the light endowed with OAM will penetrate to the blood inside. As previously mentioned, the OAM device can be used to excite resonance as well as to align or hyperpolarize the nuclei of dipoles in the blood flowing through the region of interest. The resonance from hyperpolarized nuclei is measured with the device 56 as they flow through the subject's bloodstream.

In another embodiment, with reference to FIG. 3, the hyperpolarizing device is contained entirely within the catheter 50 system. The catheter 50 includes an elongated portion 80 and a distal end 82 configured for insertion into a patient. The elongated portion 80 includes fiber optics or other light guides to transmit light from the light source 12 to the distal end 82 or, when the light source is positioned at the distal end, power for the light source. The distal end includes magnets 84 for producing the B₀ magnetic field at the distal end 82 of the catheter to define the direction of the B₀ field and the resonance frequency at the distal end, an optional gradient magnetic coil for spatially encoding the main magnetic field with gradient fields, and an RF coil 86 receiving magnetic resonance.

The light from the light source is endowed with OAM by the OAM endowing unit 13. The light endowed with OAM encounters a partially mirrored plate 88 that allows a portion of light to pass to a first objective lens 90. Another portion of light is reflected to a first mirror 92 and on to a second mirror 94 where it then passes through a second objective lens 96, which is oriented orthogonally to the first objective lens. Other optical orientations are possible to arrive at the same result and are also contemplated. Alternatively, the partially mirrored plate 88 can be a fully mirrored shutter which selectively passes the OAM endowed light to each of the objective lens.

In another embodiment, with reference to FIG. 4, a table top pH measurement system 100 includes portion for insertion of a sample 102. The table top system 100 includes light source 12, an OAM endowing unit 13, a magnet 104 for establishing the B₀ field through the sample 102, an RF receive coil 106 for receiving magnetic resonance, as well as the measurement unit 64 for calculating the pH of the sample.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A pH measurement system comprising:
a magnet defines a B₀ magnetic field with which selected dipoles preferentially align in an examination region;
an orbital angular momentum system endows electromagnetic (EM) radiation with orbital angular momentum (OAM) and transmits the OAM endowed EM radiation to the examination region to at least one of (1) enhance the preferential alignment of the selected dipoles with the B₀ magnetic field and (2) excite the aligned dipoles to resonate;
a receive coil receives resonance signals from the resonating dipoles;
an analysis or measurement unit determines a pH in the examination region by analyzing the resonance signals.

2. The pH measurement system according to claim 1, wherein the OAM system includes:
an electromagnetic (EM) radiation source which provides a light beam; and
an OAM endowing unit which endows the light with OAM and directs the OAM endowed light to the examination region.

3. The pH measurement system according to claim 1, wherein the OAM endowing unit further includes:
a liquid crystal on silicon (LCOS) panel which defines the OAM imparted onto the EM radiation.

4. The pH measurement system according to claim 1, wherein the analysis or measurement unit includes:
a processor which determines at least one of (1) a relaxation value and (2) a resonance frequency of the resonance signals.

5. The pH measurement system according to claim 1, wherein the analysis or measurement unit further includes:
a memory which stores a correlation between pH and at least one of (1) relaxation values of the selected dipoles and (2) resonance frequency of the selected dipoles.

6. The pH measurement system according to claim 1, further including:
a control unit which controls the OAM system such that the EM radiation endowed with OAM is used to excite resonance in the selected dipoles and manipulate the excited resonance to form magnetic resonance echoes.

7. The pH measurement system according to claim 6, wherein the processor analyzes the magnetic resonance echoes to determine T2 or T2* relation values.

8. The pH measurement system according to claim 1, wherein reference dipoles for which the correlation between pH and at least one of the relaxation values and resonance frequency are stored in the memory is injected into a subject and further including:
a control unit which controls the OAM system to excite resonance in both the reference dipoles and an unknown dipole in the examination region; and
wherein the processor (1) analyzes the resonance signal from the reference dipole to determine pH in the examination region and (2) correlates the determined pH in the examination region with at least one of relaxation value of the unknown dipole and a resonance frequency of the unknown dipole.

9. The pH measurement system according to claim 1, wherein at least a portion of the OAM system is disposed at a distal end of a catheter.

10. A method of measuring pH comprising:
defining a B₀ magnetic field with which selected dipoles preferentially align in an examination region;
endowing electromagnetic (EM) radiation with orbital angular momentum (OAM);
transmitting the OAM endowed EM radiation to the examination region to at least one of (1) enhance the preferential alignment of the selected dipoles with the B₀ magnetic field and (2) excite the aligned dipoles to resonate;
receiving resonance signals from the resonating dipoles;
determining a pH in the examination region by analyzing the resonance signals.

11. The method of measuring pH according to claim 10, wherein the steps of endowing electromagnetic (EM) radiation with orbital angular momentum (OAM) and transmitting the OAM endowed EM further comprises:
providing a light beam; and
endowing the light beam with OAM; and
directing the OAM endowed light to the examination region.

12. The method for measuring pH according to claim 10, wherein the step of endowing EM radiation with orbital angular momentum (OAM) further includes:
controlling characteristics of the OAM imparted to the EM radiation.

13. The method for measuring pH according to claim 10, wherein the step of determining a pH in the examination region further includes:
determining at least one of (1) a relaxation value and (2) a resonance frequency of the resonance signal.

14. The method for measuring pH according to claim 13, wherein the step of determining a pH in the examination region further includes:
comparing the at least one of (1) relaxation values of the selected dipole and (2) resonance frequency of the selected dipoles with a predetermined correlation between the at least one of the relaxation value and the resonance frequency and pH for the selected dipole.

15. The method for measuring pH according to claim 12, further including:
controlling characteristics of the OAM imparted to the EM radiation to excite resonance in the selected dipoles and manipulate the excited resonance to form magnetic resonance echoes.

16. The method for measuring pH according to claim 10, wherein the step of determining a pH in the examination region further includes:
analyzing the resonance signals to determine a T2 or T2* relation value.

17. The method for measuring pH according to claim 10, further including:
exciting resonance in both a reference dipole and an unknown dipole in the examination region to generate a resonance signal from the reference dipole and a resonance signal from the unknown dipole;
analyzing the resonance signal from the reference dipole to determine pH in the examination region; and
correlating the determined pH in the examination region with at least one of a relaxation value of the resonance signal of the unknown dipole and a resonance frequency of the resonance signal of the unknown dipole.
